(19) United States
(12) Patent Application Publication
(10) Pub. No.: US 2015/0171206 A1
(43) Pub. Date: Jun. 18, 2015

(54) Epitaxially Growing III-V Contact Plugs for MOSFETs

(71) Applicant: Taiwan Semiconductor Manufacturing Company, Ltd., Hsin-Chu (TW)

(72) Inventor: Mark van Dal, Heverlee (BE)

(73) Assignee: Taiwan Semiconductor Manufacturing Company, Ltd., Hsin-Chu (TW)

(21) Appl. No.: 14/132,450

(22) Filed: Dec. 18, 2013

(51) Int. Cl. H01L 29/78; H01L 29/417; H01L 29/423; H01L 29/66

(52) U.S. Cl. CPC H01L 29/78; H01L 29/66522; H01L 29/66431; H01L 29/41725; H01L 29/4232

(57) ABSTRACT

A Metal-Oxide-Semiconductor Field-Effect Transistor (MOSFET) includes a source/drain region comprising a first III-V compound semiconductor material, and a contact plug over and connected to the source/drain region. The contact plug includes a second III-V compound semiconductor material.

### BACKGROUND

In the formation of integrated circuits, semiconductor devices are formed on semiconductor substrates, and are then connected through metallization layers. The metallization layers are connected to the semiconductor devices through contact plugs. Also, external pads are connected to the semiconductor devices through the contact plugs and the metallization layers.

Typically, the formation process of contact plugs includes forming an Inter-Layer Dielectric (ILD) over the semiconductor devices, forming contact openings in the ILD, and filling a metallic material in the contact openings. With the increasing down-scaling of integrated circuits, however, the above-discussed processes experience shortcomings. While the horizontal dimensions (for example, the poly-to-poly pitch between neighboring polysilicon lines) are continuously shrinking, the diameters of contact plugs and the contact area between contact plugs and the underlying salicide regions are reduced. The thickness of the ILD is not reduced accordingly to the same scale as the reduction of the lateral dimensions of the contact plugs. Accordingly, the aspect ratios of the contact plugs increase, causing the contact formation process to be increasingly more and difficult.

The down-scaling of integrated circuits results in several problems. First, it is increasingly more difficult to fill the contact openings without causing seam holes (voids) therein. In addition, when the lateral sizes of the contact plugs reduce, the sizes of seam holes do not reduce proportionally. This not only causes the effective area of the contact plugs for conducting currents to reduce non-proportionally, but also results in the subsequently formed contact etch stop layer and metal lines to fall into the seam holes, and hence results in reliability problems. As a result, the process window for forming the contact openings becomes narrower and narrower, and the formation of contact plugs has become the bottleneck for the down-scaling of integrated circuits.

### BRIEF DESCRIPTION OF THE DRAWINGS

For a more complete understanding of the embodiments, and the advantages thereof, reference is now made to the following descriptions taken in conjunction with the accompanying drawings, in which:

FIGS. 1 through 8C are cross-sectional views of intermediate stages in the manufacturing of a Metal-Oxide-Semiconductor Field-Effect Transistor (MOSFET) and the respective contact plugs in accordance with some exemplary embodiments; and

FIGS. 9 through 12 illustrates cross-sectional views of intermediate stages in the manufacturing of a MOSFET and the contact plugs in accordance with some alternative exemplary embodiments.

### DETAILED DESCRIPTION OF ILLUSTRATIVE EMBODIMENTS

The making and using of the embodiments of the disclosure are discussed in detail below. It should be appreciated, however, that the embodiments provide many applicable concepts that can be embodied in a wide variety of specific contexts. The specific embodiments discussed are illustrative, and do not limit the scope of the disclosure.

A Metal-Oxide-Semiconductor Field-Effect Transistor (MOSFET) and the respective contact plugs and the method of forming the same are provided in accordance with various exemplary embodiments. The intermediate stages of forming the MOSFET and the contact plugs are illustrated. The variations of the embodiments are discussed. Throughout the various views and illustrative embodiments, like reference numbers are used to designate like elements.

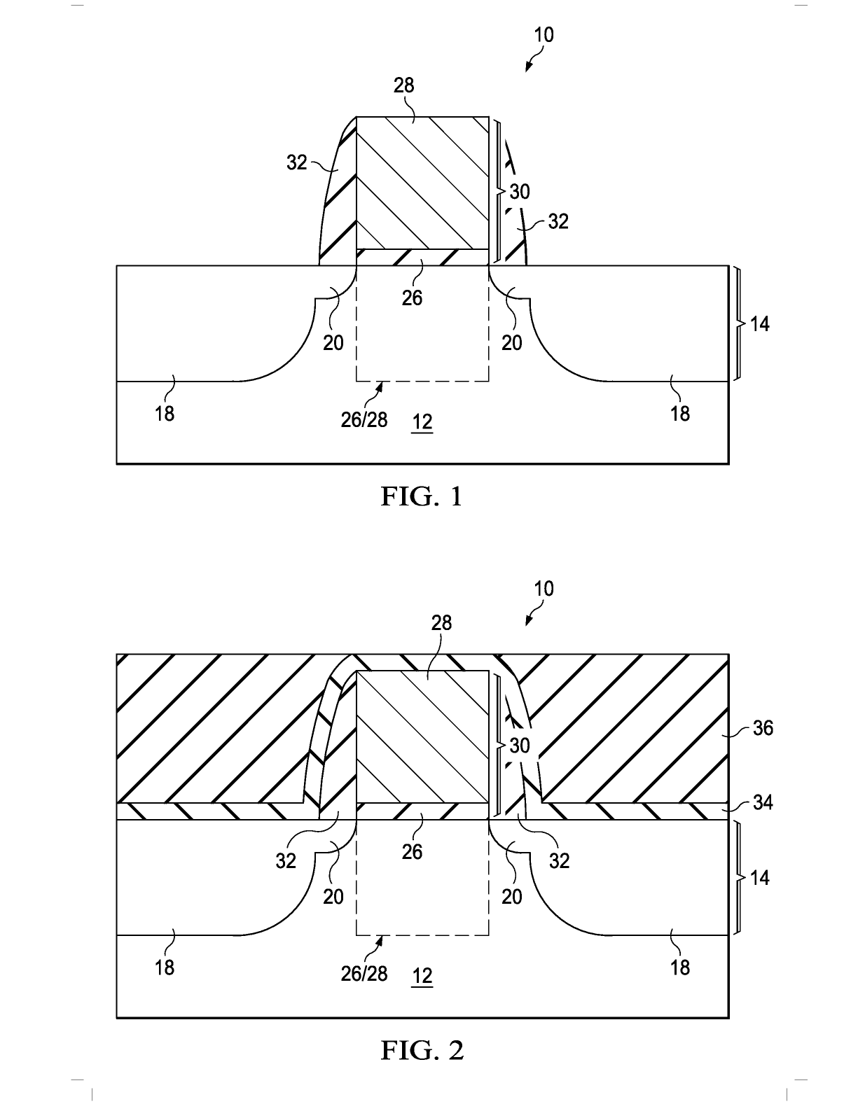

FIGS. 1 through 8C illustrate cross-sectional views of intermediate stages in the manufacturing of MOSFETs and contact plugs for connecting to the MOSFETs in accordance with some exemplary embodiments. Referring to FIG. 1, MOSFET 10 is formed at the top surface of semiconductor substrate 12. In some embodiments, semiconductor substrate 12 comprises a III-V compound semiconductor, which may comprise InAs, AlAs, GaAs, InP, GaN, InGaAs, InAlAs, GaSb, AlSb, AlP, GaP, InSb, or combinations thereof. In alternative embodiments, semiconductor substrate 12 comprises silicon, silicon germanium, or the like. Substrate 12 has a crystalline structure in accordance with some embodiments.

MOSFET 10 may further include source and drain regions (referred to as source/drain regions hereinafter) 18, and Lightly Doped source/Drain (LDD) regions 20. Source/drain regions 18 and LDD regions 20 are formed of III-V compound semiconductor materials, and may be selected from the group consisting essentially of InAs, AlAs, GaAs, InP, GaN, InGaAs, InAlAs, GaSb, AlSb, ALP, GaP, InSb, and combinations thereof. Additional impurities may also be doped in source/drain regions 18 and LDD regions 20 to make these regions either p-type regions or n-type regions. For example, when MOSFET 10 is a p-type MOSFET, acceptor impurities such as beryllium, zinc, cadmium, silicon, and germanium may be doped in source/drain regions 18 and LDD regions 20. Conversely, when MOSFET 10 is an n-type MOSFET, donor impurities such as selenium, tellurium, silicon, and germanium may be doped in source/drain regions 18 and LDD regions 20.

Gate stack 30, which includes gate dielectric 26 and gate electrode 28, is formed over active region 16. Gate dielectric 26 may be formed of silicon oxide, silicon nitride, silicon oxynitride, high-k dielectric materials such as hafnium oxide, lanthanum oxide, aluminum oxide, or multi-layers thereof. Gate electrode 28 may include a silicon-containing portion (such as a polysilicon region). Gate spacers 32 are formed on the sidewalls of the gate stack. In some embodiments, MOSFET 10 is a planar MOSFET, and hence gate stack 30 is formed on the top surface (but not on sidewalls) of substrate 12. In alternative embodiments, MOSFET 10 is a Fin Field-Effect Transistor (FinFET). In these embodiments, substrate 12 includes a portion protruding above the remaining parts of substrate 12 and above Isolation regions (such as shallow trench isolation regions, not shown) to form fin 14. Gate stack 30 thus includes a top portion over the top surface of fin 14, and sidewall portions on the sidewalls of fin 14. The sidewall portions (marked as 26/28) are not in the illustrated plane, and hence are illustrated using dashed lines.

Gate stack 30 may be formed using a gate-first approach, as illustrated in FIG. 1. In alternative embodiments, gate stack 30 is formed using a gate-last approach, which gate stack is sometimes referred to as a replacement gate. In which embodiments, gate dielectric 26 includes portions on the sidewalls of gate electrode 28.

Referring to FIG. 2, Contact Etch Stop Layer (CESL) 34 and Inter-Layer Dielectric (ILD) 36 are formed. In some embodiments, CESL 34 comprises a dielectric material such as oxide, nitride, carbide, or the like. CESL 34 may also have a multi-layer structure having more than one layer. ILD 36 may comprise Flowable oxide formed using, for example Flowable Chemical Vapor Deposition (FCVD). ILD 36 may also be a spin-on glass formed using spin-on coating. For example, ILD 36 may comprise Phospho-Silicate glass (PSG), Boro-Silicate Glass (BSG), Boron-Doped Phospho-Silicate Glass (BPSG), Tetraethyl Orthosilicate (TEOS) oxide, TiN, SiOC, or other low-k non-porous dielectric materials.

A planarization such as a Chemical Mechanical Polish (CMP) is then performed to level the top surfaces of CESL 34 and ILD 36 with each other. In some embodiments, as shown in FIG. 2, the CMP is performed using CESL 34 as a CMP stop layer. Accordingly, CESL 34 includes a portion overlapping gate electrode 28.

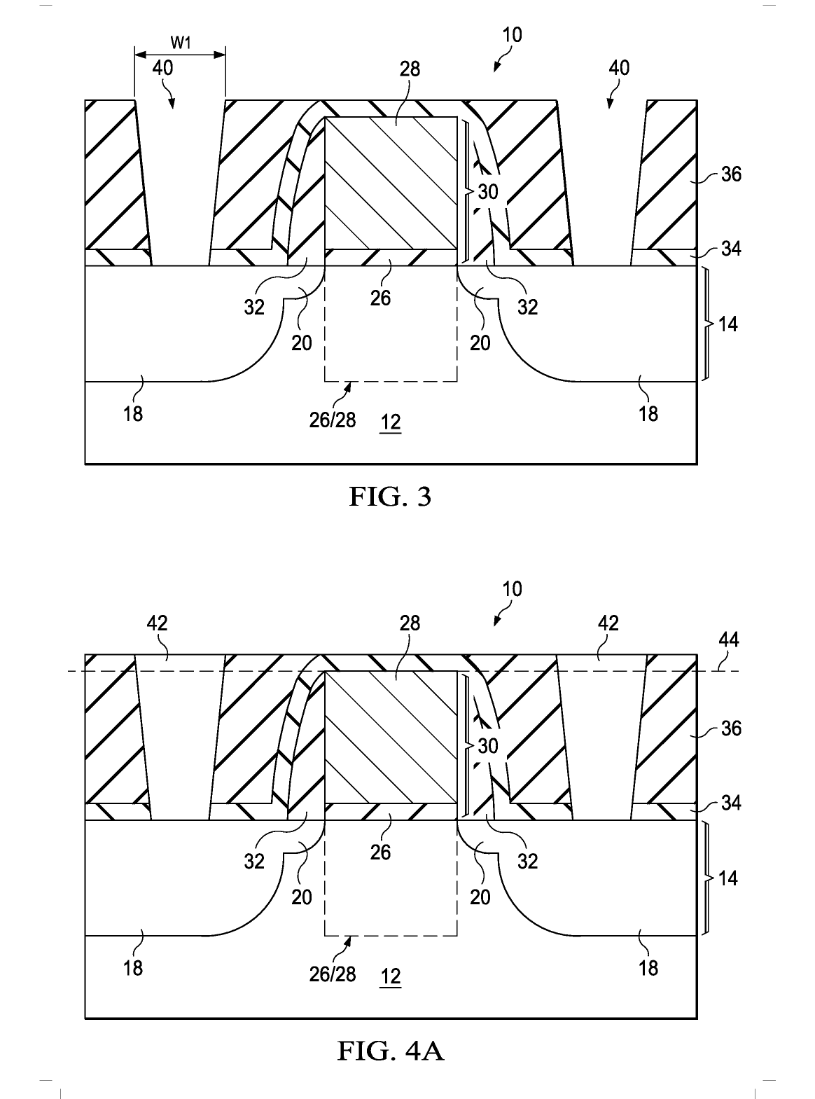

Next, referring to FIG. 3, contact openings 40 are formed in ILD 36 and CESL 34. The formation of contact openings 40 includes etching ILD 36 to form contact openings 40 using CESL 34 as an etch stop layer, and then etching CESL 34 to expose the underlying source/drain regions 18. In some embodiments, the lateral sizes such as the width W1 of contact openings 40 are smaller than about 50 nm. It is appreciated, however, that the values recited throughout the description are merely examples, and may be changed to different values.

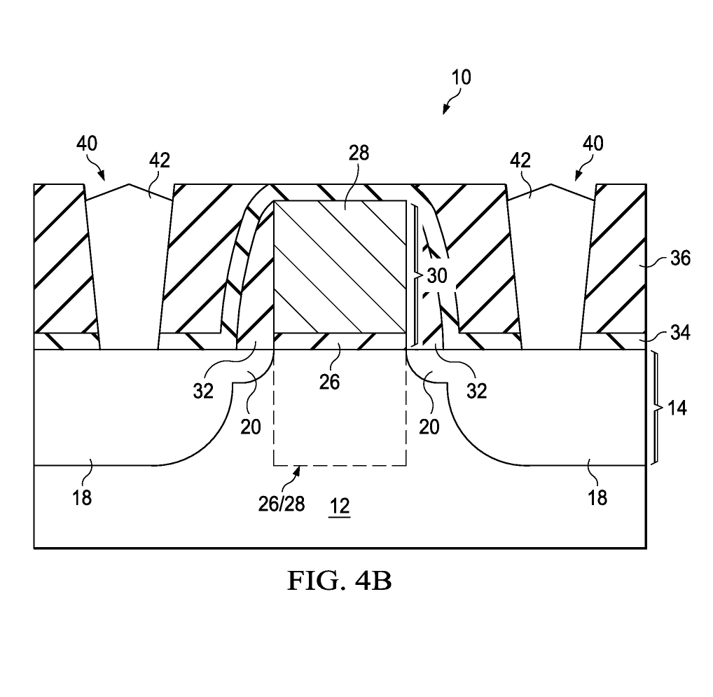

Referring to FIGS. 4A and 4B, epitaxy contact plugs 42 are grown in contact openings 40 (FIG. 3) through selective epitaxy, with the epitaxially grown material grown on the exposed source/drain regions 18, and not on the exposed dielectric materials such as CESL 34 and ILD 36. The epitaxy may be performed through Metal-Organic Chemical Vapor Deposition (MOCVD) in some exemplary embodiments. Epitaxy contact plugs 42 comprise a III-V compound semiconductor material, which is elected from, and is not limited to, InAs, AlAs, GaAs, InP, GaN, InGaAs, InAlAs, GaSb, AlSb, AlP, GaP, InSb, and combinations thereof. In some embodiments, epitaxy contact plugs 42 is formed of a same material as the underlying sourced/drain regions 18, which are also III-V compound semiconductor regions. In alternative embodiments, epitaxy contact plugs 42 and source/drain regions 18 are formed of different III-V compound semiconductors. Epitaxy contact plugs 42 may be formed of a III-V compound semiconductor having a bandgap smaller than the bandgap of the underlying source/drain regions 18 in these embodiments. In some embodiments, when MOSFET 10 is an n-type MOSFET, epitaxy contact plugs 42 comprise InAs, InGaAs, GaAs, InSb, or combinations thereof. When MOSFET 10 is a p-type MOSFET, epitaxy contact plugs 42 comprise InSb, InGaAs, GaSb, or combinations thereof.

Depending on the conductivity type of MOSFET 10, epitaxy contact plugs 42 may be doped with a p-type or an n-type impurity to reduce its resistivity. The doped impurity has a same conductivity type as the conductivity type of the impurity doped in source and drain regions 18. For example, when MOSFET 10 is a p-type MOSFET, acceptor impurities such as beryllium, zinc, cadmium, silicon, and germanium may be doped in epitaxy contact plugs 42. Conversely, when MOSFET 10 is an n-type MOSFET, donor impurities such as selenium, tellurium, silicon, or germanium may be doped in epitaxy contact plugs 42. The doping is in-situ performed when the epitaxy proceeds. The impurity doped in epitaxy contact plugs 42 may be the same as, or different from, the impurity doped in source/drain regions 18.

The epitaxy may be performed until the top surfaces of epitaxy contact plugs 42 are higher than the top surfaces of ILD 36. A CMP is then performed to remove the excess portions of epitaxy contact plugs 42, so that the top surfaces of epitaxy contact plugs 42 are level with the top surface of ILD 36, as illustrated in FIG. 4A. In some embodiments, the CMP is performed using CESL 34 as a CMP stop layer, as shown in FIG. 4A. In alternative embodiments, the CMP is performed using gate electrode 28 as a CMP stop layer. The resulting structure is similar to the structure shown in FIG. 4A, except that the portions of ILD 36, CESL 34, and epitaxy contact plugs 42 over line 44 are removed.

FIG. 4B illustrates the epitaxy for forming epitaxy contact plugs 42 in accordance with alternative embodiments. In these embodiments, the epitaxy of epitaxy contact plugs 42 is carefully controlled, so that the growth of epitaxy contact plugs 42 stop when the top surfaces of epitaxy contact plugs 42 are substantially level with the top surface of ILD 36. The height difference between the top surfaces of epitaxy contact plugs 42 and the top surface of ILD 36 is controlled to be small. Accordingly, no CMP is needed to level the top surfaces of epitaxy contact plugs 42 and the top surface of ILD 36 after the epitaxy. Epitaxy contact plugs 42 in these embodiments may have facets, for example, with each of epitaxy contact plugs 42 having a pyramid top surface that has four surfaces converge at the top, with each of the top surfaces being a triangle.

An advantageous feature of the embodiments of the present disclosure is that contact plugs 42 are formed through epitaxy, and hence contact plugs 42 may be formed in very narrow contact openings.

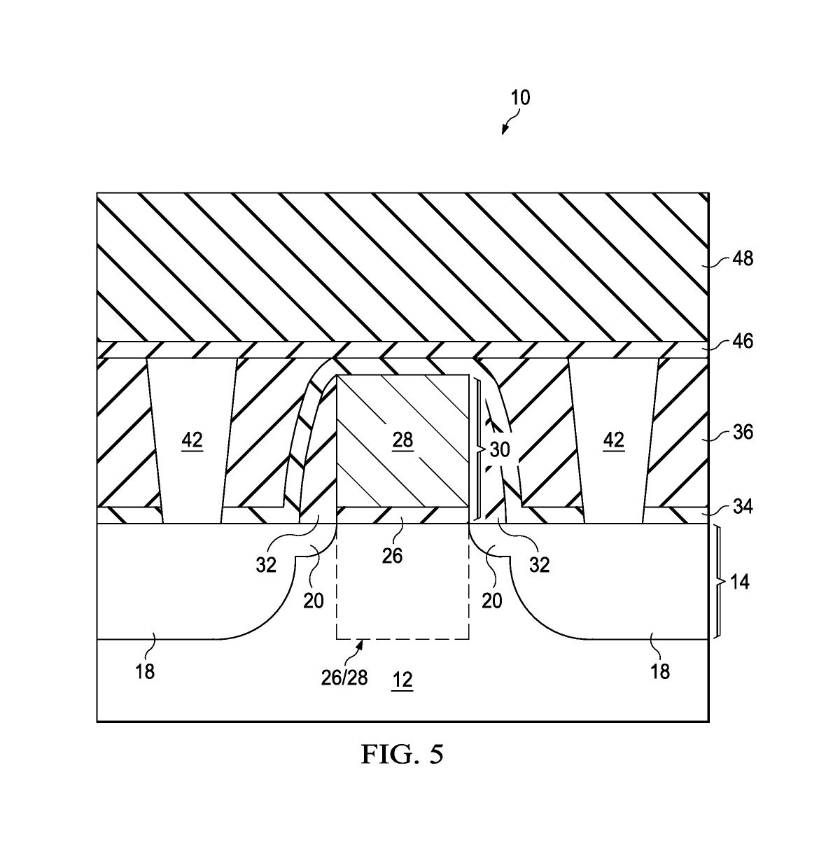

Referring to FIG. 5, etch stop layer 46 is formed over ILD 36, ESL 34, and epitaxy contact plugs 42. Etch stop layer 46 comprises a dielectric material such as silicon carbide, silicon nitride, silicon oxynitride, or the like. Dielectric layer 48 is further formed over etch stop layer 46. In some embodiments, dielectric layer 48 is an addition ILD, and hence may be formed of a non-porous dielectric material, which may be selected from the same candidate materials of ILD 36. In alternative embodiments, dielectric layer 48 is an Inter-Metal Dielectric (IMD), and may comprise a low-k dielectric material with a k value lower than about 3.0, lower than about 2.5, or lower than about 2.0. In these embodiments, dielectric layer 48 may be a porous low-k dielectric layer.

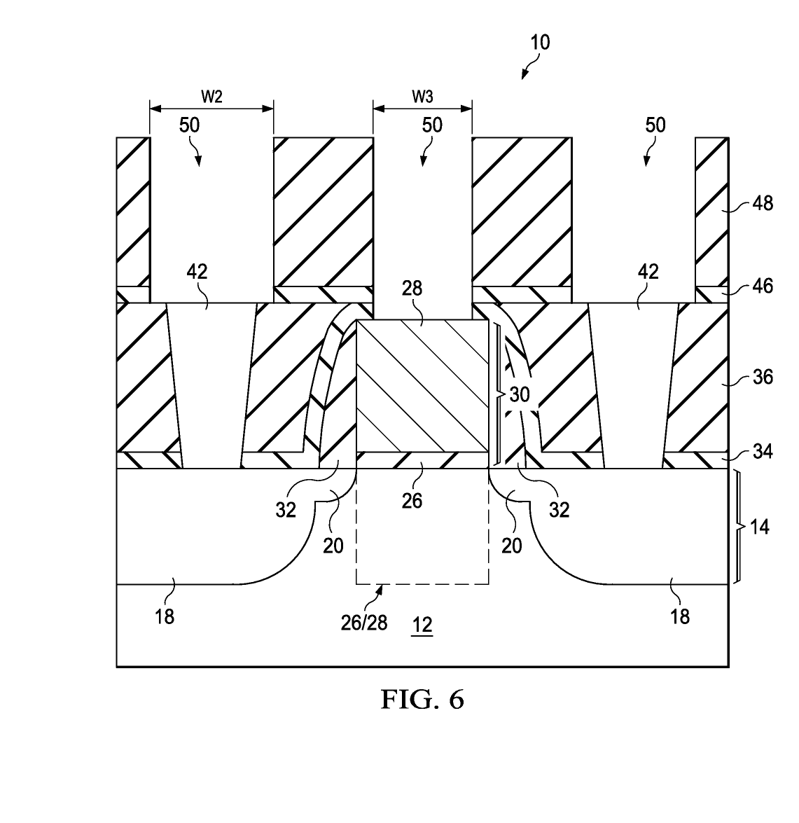

FIG. 6 illustrates the formation of openings 50, which are formed by etching dielectric layers 48 and ESL 46. In some embodiments, the widths W2 and W3 of openings 50 are greater than width W1 of contact openings 40 (FIG. 3). For example, ratios W2/W1 and W3/W1 may be greater than about 2 or greater. Accordingly, metallic materials may be easily filled into openings 50.

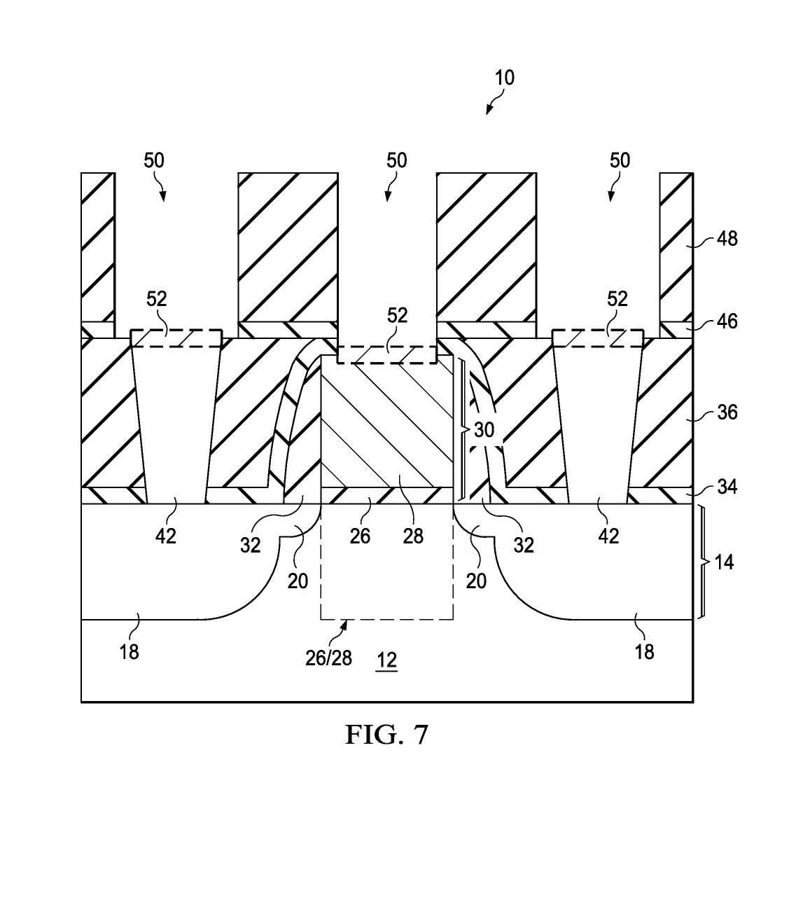

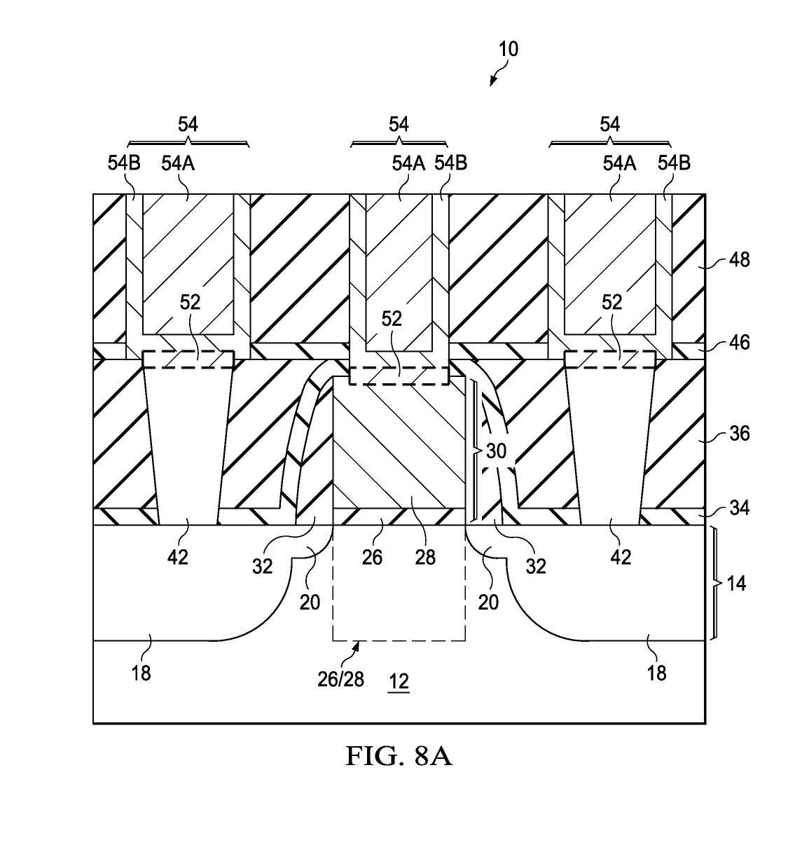

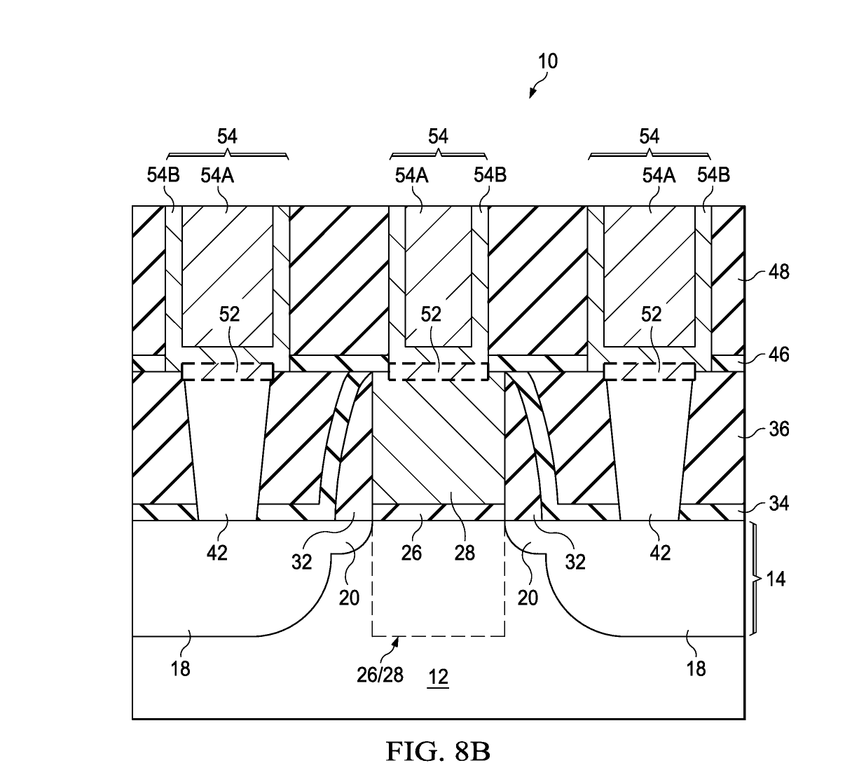

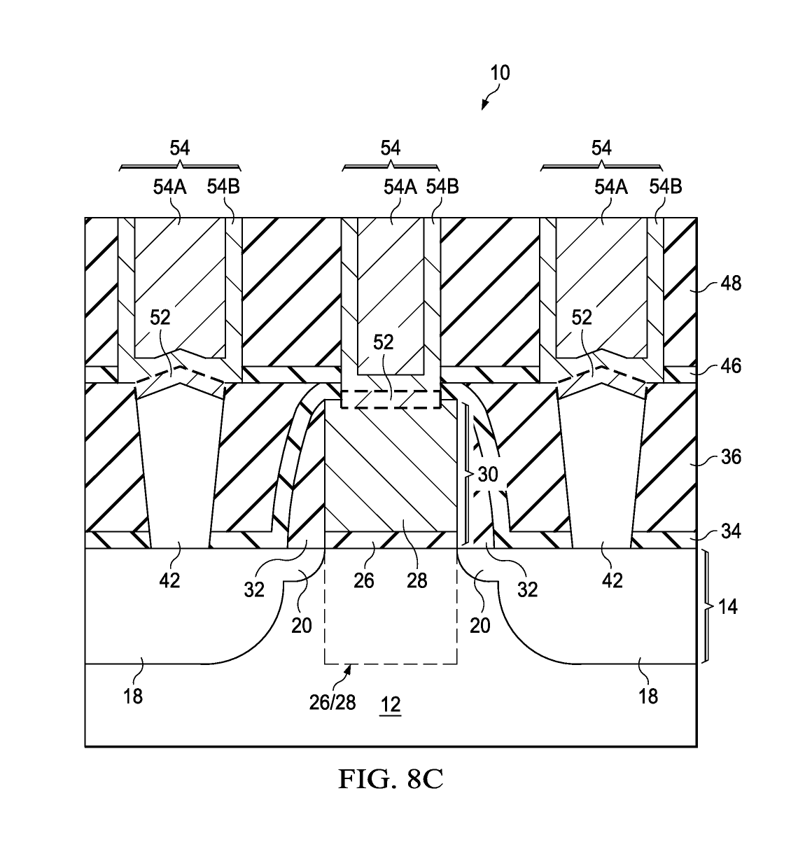

FIG. 7 illustrates the formation of silicide regions 52 in accordance with some exemplary embodiments. The formation of silicide regions 52 may include forming a blanket metal layer (not shown) comprising a metal such as nickel, cobalt, or the like. The blanket metal layer extends into openings 50 to contact epitaxy contact plugs 42. An annealing is then performed to react the metal layer with the exposed epitaxy contact plugs 42 (and possibly gate electrode 28) to form silicide regions 52, and then removing the un-reacted portions of the metal layer. In alternative embodiments, the formation of silicide regions 52 is skipped, and the subsequently formed metallic features 54 (FIGS. 8A, 8B, and 8C) is in contact with epitaxy contact plugs 42.

Referring to FIG. 8A, metallic features 54 are formed in openings 50 (FIG. 7). In some embodiments, metallic features 54 include diffusion barrier layer 54A, and metallic material 54B filling the remaining portions of openings 50. Diffusion barrier layer 54A may include titanium, titanium nitride, tantalum, tantalum nitride, or the like. The filling metal 54B may include copper, tungsten, aluminum, or alloys thereof. In the embodiments in which dielectric layer 48 is an ILD, metallic features 54 are also contact plugs. In the embodiments in which dielectric layer 48 is an IMD, metal features 54 may be metal lines, which are sometimes referred to as parts of metallization layer Ml.

FIGS. 8B and 8C illustrate the device in accordance with alternative embodiments. In FIG. 8B, the portions of CESL 34 over the top surface of gate electrode 28 is removed in the CMP step in FIG. 4A. FIG. 8C illustrates yet an alternative embodiments. The device shown in FIG. 8C is obtained from the structure shown in FIG. 4B, wherein epitaxy contact plugs 42 have faceted top surfaces. Accordingly, silicide regions 52 also have faceted surfaces.

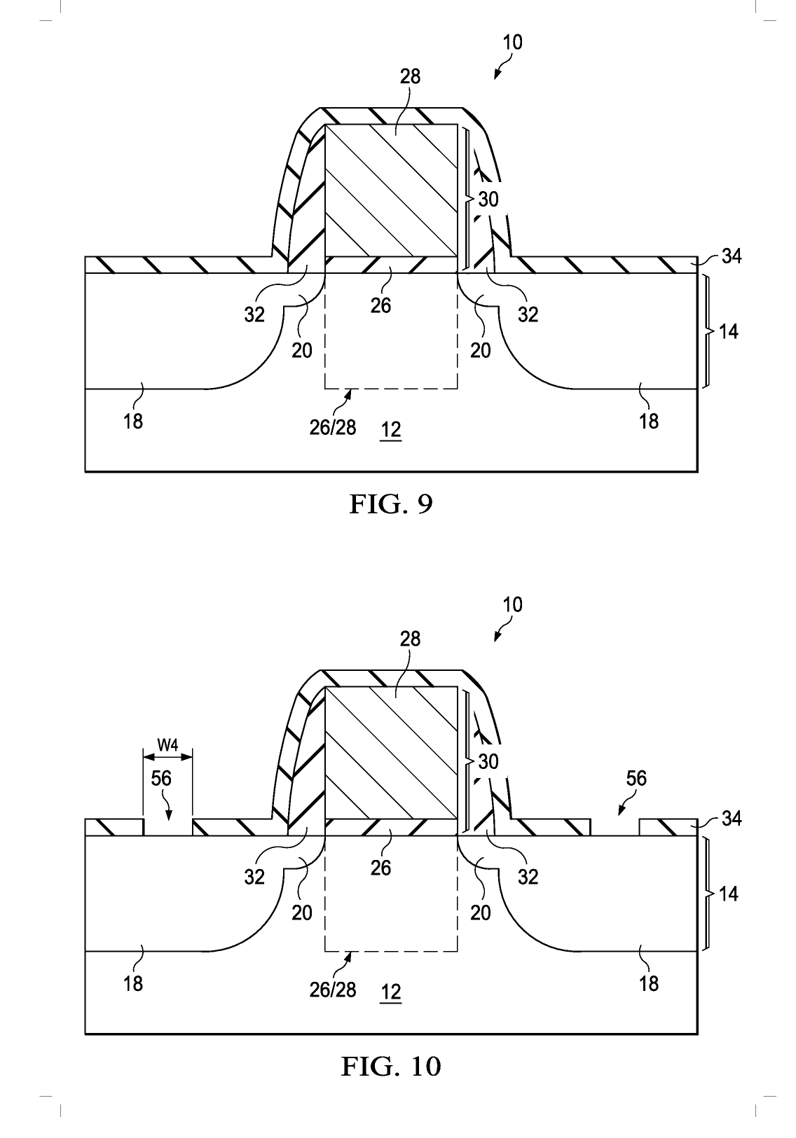

FIGS. 9 through 12 illustrate the intermediate stages in the formation of MOSFET 10 and the epitaxy contact plugs in accordance with alternative embodiments. Unless specified otherwise, the materials and the formation methods of the components in these embodiments are essentially the same as the like components, which are denoted by like reference numerals in the embodiments shown in FIGS. 1 through 8C. The details regarding the formation processes and the materials of the components shown in FIGS. 9 through 12 may thus be found in the discussion of the embodiment shown in FIGS. 1 through 8C.

The initial structure of these embodiments is essentially the same as shown in FIG. 1. Next, referring to FIG. 9, CESL 34 is formed. Before the formation of ILD, CESL 34 is patterned to form openings 56, as shown in FIG. 10. The lateral size W1 is very small, for example, smaller than about 20 nm.

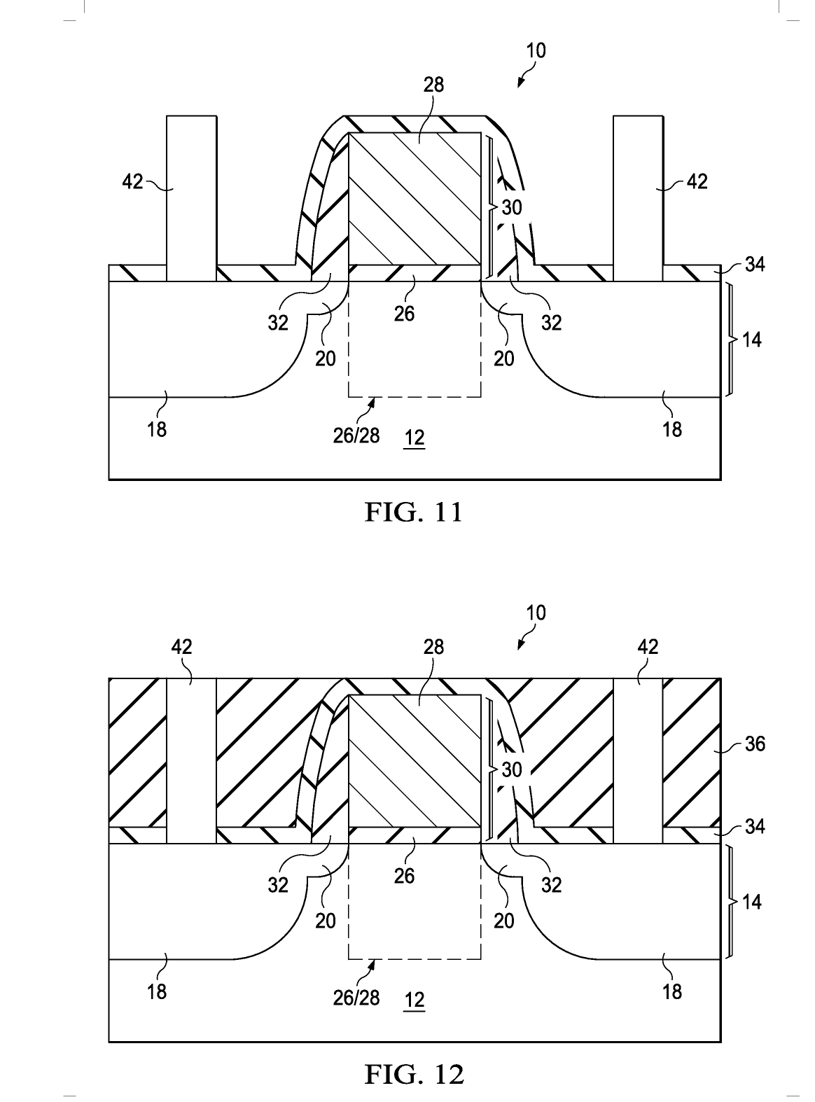

Next, nanowires 42, which are also epitaxy contact plugs, are grown from openings 56, as shown in FIG. 11. The epitaxy may be performed through MOCVD in some exemplary embodiments. Openings 56 in FIG. 10 act as the template for defining the top-view shape of epitaxy contact plugs 42. The formation is achieved through epitaxy. In some embodiments, to form epitaxy contact plugs 42, Vapor-Liquid-Solid (VLS) synthesis is used. The VLS may use small metal particles (such as gold particles) that act as a catalyst for the nanowire growth. In the exemplary embodiments in which indium is included in the epitaxy contact plugs 42 that are to be grown, indium itself acts as a catalyst, and no metal catalyst is needed.

When nanowires 42 that comprise InAs are to be grown in accordance with some embodiments, trimethylarsenic (TMA) or arsene (AsH₃) may be used as the precursor for providing arsenic, and trimethylindium (TMI) may be used as the precursor for providing indium. Prior to the growth, a surface cleaning may be be performed to remove the native oxide. In some embodiments, the surface clean is performed using HCl solution, and the cleaning time may be about one minute, for example. During the nanowire growth, nucleation of the nanowires 42 is incurred first. This may be achieved at low growth temperatures between about 350° C. and about 450° C. The subsequent growth of nanowires 42 may be performed at temperatures between about 300° C. and about 600° C. During the nanowire growth, the chamber pressure may be between about 100 mbar and about 400 mbar. The carrier gas flow rate may be between about 25 sccm and about 100 sccm. The growth time may be between about 10 seconds and about 1,000 seconds. The carrier gas may include hydrogen (H₂). To minimize lateral growth, a low V/III precursor ratio (the flow rate ratio of the group-V precursor to group-III precursor) may be used. For example, when the precursors include AsH₃ and TMI, ratio AsH₃/TMI may be between about 5 and about 100. Furthermore, a high growth temperature suppresses the lateral growth. The optimum vertical growth conditions are related with various factors, and may be found through experiments.

Through these process conditions, epitaxy contact plugs 42 grow vertically without expanding laterally. Accordingly, the top portion, the bottom portion, and the intermediate portions of nanowires 42 have the same lateral dimensions and shapes, which lateral dimensions and the shapes are the same as the respective lateral dimensions and shapes of openings 56 (FIG. 10). The vertical growth of epitaxy contact plugs 42 is stopped when the top surfaces of epitaxy contact plugs 42 are higher than the top surface of gate electrode 28, or higher than the top surface of the top portion of CESL 34, which top portion of CESL 34 being overlapping gate electrode 28.

Next, referring to FIG. 12, ILD 36 is formed, followed by a CMP to level the top surfaces of epitaxy contact plugs 42 with the top surface of ILD 36. The CMP may be performed using CESL 34 as a CMP stop layer, resulting in the structure shown in FIG. 12. Alternatively, the CMP is performed using gate electrode 28 as a CMP stop layer, wherein the CMP may be stopped at the level 44 shown in FIG. 4A. In subsequent process steps, the steps shown in FIGS. 5 through 8B are performed, and the resulting device is similar to what is shown in FIGS. 8A and 8B, except that the epitaxy contact plugs 42 formed using the embodiments in FIGS. 1 through 4 have slightly tapered profile, with upper portions increasingly larger than lower portions, while the epitaxy contact plugs 42 formed using the embodiments in FIGS. 9 through 12 have vertical profiles.

The embodiments of the present disclosure have some advantageous features. In accordance with the embodiments of the present disclosure, contact plugs are formed through epitaxially growing a III-V compound semiconductor. Since the epitaxially grown contact plugs may fill very narrow contact plug openings, the problems experienced in the formation of conventional metal contact plugs are eliminated. Furthermore, since the epitaxy contact plugs and the underlying source/drain regions are formed of similar or the same material(s), and the epitaxy contact plugs are epitaxially grown from the source/drain regions, there is no contact resistance (or substantially no contact resistance) resulted between the epitaxy contact plugs and the source/drain regions.

In accordance with some embodiments, a MOSFET includes a source/drain region including a first III-V compound semiconductor material, and a contact plug over and connected to the source/drain region. The contact plug includes a second III-V compound semiconductor material.

In accordance with other embodiments, an integrated circuit device includes a III-V compound semiconductor substrate, a gate dielectric over the III-V compound semiconductor substrate, a gate electrode over the gate dielectric, and a source/drain region on a side of the gate electrode. The source/drain region includes a first III-V compound semiconductor material. A contact plug is over and in contact with the source/drain region, wherein the contact plug includes a second III-V compound semiconductor material. An ILD is over the source/drain region, wherein the gate electrode and the contact plug extend into the ILD.

In accordance with yet other embodiments, a method includes forming a MOSFET including forming a gate dielectric over a semiconductor substrate, forming a gate electrode over the gate dielectric, and forming a source/drain region including a first III-V compound semiconductor material on a side of the gate electrode. The method further includes forming a dielectric layer over the source/drain region, forming an opening in the dielectric layer to reveal the source/drain region, and performing an epitaxy to grow a contact plug in the opening. The contact plug includes a second III-V compound semiconductor material.

Although the embodiments and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

1. An integrated circuit device comprising:
a Metal-Oxide-Semiconductor Field-Effect Transistor (MOSFET) comprising:
a source/drain region comprising a first III-V compound semiconductor material; and
a contact plug over and connected to the source/drain region, wherein the contact plug comprises a second III-V compound semiconductor material.

2. The integrated circuit device of claim 1, wherein the MOSFET further comprises:
a gate dielectric;
a gate electrode over the gate dielectric; and
an Inter-Layer Dielectric (ILD) over the source/drain region, wherein the gate electrode comprises a portion in the ILD, and wherein the contact plug is disposed in the ILD.

3. The integrated circuit device of claim 1, wherein the source/drain region and the contact plug comprise a same III-V compound semiconductor material.

4. The integrated circuit device of claim 1, wherein the first III-V compound semiconductor material has a first bandgap, and wherein the second III-V compound semiconductor material has a second bandgap smaller than the first bandgap.

5. The integrated circuit device of claim 6 further comprising:
a metal silicide region over and contacting the contact plug, wherein bottom surfaces of the metal silicide region are in physical contact with the faceted top surfaces of the contact plug; and
a metallic feature overlying and contacting the metal silicide region.

6. The integrated circuit device of claim 1, wherein the contact plug has faceted top surfaces.

7. The integrated circuit device of claim 1, wherein the second III-V compound semiconductor material has a crystalline structure.

8. An integrated circuit device comprising:
a III-V compound semiconductor substrate;
a gate dielectric over the III-V compound semiconductor substrate;
a gate electrode over the gate dielectric;
a source/drain region on a side of the gate electrode, wherein the source/drain region comprises a first III-V compound semiconductor material;
a contact plug over and in contact with the source/drain region, wherein the contact plug comprises a second III-V compound semiconductor material; and
an Inter-Layer Dielectric (ILD) over the source/drain region, wherein the gate electrode and the contact plug extend into the ILD.

9. The integrated circuit device of claim 8 further comprising a contact etch stop layer between the ILD and the source/drain region, with the contact plug extending through the contact etch stop layer.

10. The integrated circuit device of claim 8, wherein the second III-V compound semiconductor material has a crystalline structure.

11. The integrated circuit device of claim 8, wherein the first III-V compound semiconductor material and the second III-V compound semiconductor material are a same III-V compound semiconductor material.

12. The integrated circuit device of claim 8, wherein the second III-V compound semiconductor material has a bandgap lower than a bandgap of the first III-V compound semiconductor material.

13. The integrated circuit device of claim 8, wherein the contact plug has faceted top surfaces.

14. The integrated circuit device of claim 13 further comprising a silicide region over and in contact with the faceted top surfaces of the contact plug.

15.-20. (canceled)

21. An integrated circuit device comprising:
a semiconductor substrate having a major bottom surface; and
a Metal-Oxide-Semiconductor Field-Effect Transistor (MOSFET) at a surface of the semiconductor substrate, the MOSFET comprising:
a source/drain region comprising a first III-V compound semiconductor material; and
a contact plug over and in physical contact with the source/drain region, wherein the contact plug comprises a second III-V compound semiconductor material, and the contact plug has a top surface comprising:
a first portion; and
a second portion physically connected to the first portion, wherein the first portion and the second portion are neither parallel to nor perpendicular to the major bottom surface of the semiconductor substrate.

22. The integrated circuit device of claim 21 further comprising a silicide region over the contact plug, wherein the silicide region comprises:
a first bottom surface in contact with the first portion of the top surface of the contact plug; and
a second bottom surface in contact with the second portion of the top surface of the contact plug.

23. The integrated circuit device of claim 22, wherein edges of the silicide region are co-terminus with edges of the contact plug.

24. The integrated circuit device of claim 22 further comprising:
a gate dielectric over the semiconductor substrate;
a gate electrode over the gate dielectric; and
an Inter-Layer Dielectric (ILD) over the source/drain region, wherein the contact plug extends from substantially a top surface of the ILD to a bottom surface of the ILD.

25. The integrated circuit device of claim 21, wherein the source/drain region and the contact plug comprise a same III-V compound semiconductor material.

26. The integrated circuit device of claim 21, wherein the first III-V compound semiconductor material has a first bandgap, and wherein the second III-V compound semiconductor material has a second bandgap smaller than the first bandgap.
